(19) United States
(12) Patent Application Publication
(10) Pub. No.: US 2026/0280410 A1
(43) Pub. Date: Sep. 17, 2026

(54) DRIVING POWER SWITCHES WITH VARIABLE CURRENTS

(71) Applicant: POWER INTEGRATIONS, INC,, SAN JOSE, CA (US)

(72) Inventors: Felix Budde, Arnsberg-Neheim (DE); Nicolas Galante, Biel (CH); Matthias Peter, Orpund (CH); Jan Michael Spiekermann, Menden (DE); Camillo Stefanucci, Pieterlen (CH); Andreas Volke, Soest (DE)

(73) Assignee: POWER INTEGRATIONS, INC,, SAN JOSE, CA (US)

(21) Appl. No.: 19/683,575

(22) Filed: May 20, 2026

Related U.S. Application Data
(63) Continuation-in-part of application No. PCT/IB2024/052207, filed on Mar. 7, 2024.
(60) Provisional application No. 63/612,452, filed on Dec. 20, 2023.
(60) Provisional application No. 63/829,094, filed on Jun. 24, 2025.

(51) Int. Cl. H02M 1/08; H02M 7/537; H03K 17/567

(52) U.S. Cl. CPC H02M 1/08; H02M 7/537; H03K 17/567

(57) ABSTRACT

A current-source gate driver includes circuitry that is configured to determine a rate of change of a current flowing through a power switch and generate a signal indicative of the rate of change of the current flowing through a power switch and a variable current source configured to output a drive current to a control terminal of a power switch, wherein the variable current source is configured to decrease magnitude of the drive current in response to the signal indicating that a rate of change in the current flowing through the power switch is positive.

### CROSS-REFERENCE TO RELATED APPLICATIONS

This application is a continuation-in-part of International Patent Application No. PCT/IB2024/052207, filed Mar. 7, 2024, which claims the benefit of U.S. Provisional Application No. 63/612,452 filed on Dec. 20, 2023, hereby incorporated by reference in their entirety.

This application claims the benefit of U.S. Provisional Application No. 63/829,094, filed Jun. 24, 2025, hereby incorporated by reference in its entirety.

### BACKGROUND INFORMATION

### Field of the Disclosure

This invention relates to driving the control terminals (e.g., gates) of power transistors with variable currents.

### Background

Power switches are switching devices designed to switch relatively high voltages and currents. Examples of power switches include insulated gate bipolar transistors (IGBTs), metal-oxide-semiconductor field-effect transistors (MOSFETs), high-electron-mobility transistors (HEMTs), and the like. These power switches are commonly fabricated using semiconductor materials such as silicon, silicon carbide, gallium nitride, or other semiconductor materials. In some cases, individual power switches will include more than one physical transistor. For example, two transistors in a cascode configuration can form a single power switch.

In practice, power switches are generally associated with dedicated control, communication, and fault protection circuitry. For example, the provision of drive signals to a power switch can be handled by gate driver circuitry. Gate drivers provide an interface between the higher-power power switches and lower-power control circuitry. For example, gate drivers can receive lower power control, data, or other signals from a controller or microprocessor and provide drive signals to control terminals of power switches.

Other examples of circuitry that can be associated with power switches include desaturation (DESAT) protection circuitry, clamping circuitry, over current protection circuitry, and the like. In many cases, such circuitry is integrated with gate driver circuitry and they may be sold as a single commercial unit.

Gate drivers can generally be classified as voltage source gate drivers or current source gate drivers. In idealized form, voltage source gate drivers maintain a fixed output voltage regardless of load and the current provided to the control terminal of the power switch is a function of, e.g., that output voltage, the voltage at the control terminal of the power switch, and the impedance between the control terminal and the output of the voltage source gate driver. In the context of insulated gate bipolar transistor power switches, the control terminal is a gate and the impedance is referred to as a gate resistor, a gate turn-on or turn-off resistor, or the like. As an aside, although ideal voltage source gate drivers do not exist, real-world devices are generally capable of mimicking idealized behavior over a range of operational conditions.

In idealized form, current source gate drivers maintain a fixed output current that is—in theory—independent of the voltage at the control terminal of the power switch. Once again, although ideal current source gate drivers do not exist, real-world devices are generally capable of mimicking idealized behavior over a range of operational conditions.

### SUMMARY OF THE DISCLOSURE

The rate of change of current, often written as di/dt, can provide useful information about the state of the power switch. The control terminal of a power switch (e.g., the gate of an IGBT) may be controlled by current from a variable current source. As disclosed herein, circuitry for determining the rate of change of an output current (e.g., an emitter current of an IGBT) may be used to provide a control or feedback signal to the variable current source. In response to the signal the variable current source may vary the amount of current provided to the control terminal to advantageously enhance the switching behavior and performance of the power switch.

### BRIEF DESCRIPTION OF THE DRAWINGS

Non-limiting and non-exhaustive embodiments of driving power switches with variable currents are described with reference to the following figures, wherein like reference numerals refer to like parts throughout the various views unless otherwise specified.

FIG. 1 is a schematic representation of circuitry in which the control terminal of an IGBT power switch is driven by a current-source driver that includes a variable current source.

FIG. 2 includes representations of time traces of various waveforms that arise during driving of the gate of an IGBT power switch with a variable current source during a transition from the OFF state to the ON state.

FIG. 3 is a schematic representation of circuitry in which the control terminal of an IGBT power switch is driven by a current-source driver that includes a variable current source according to an embodiment of the present disclosure.

FIG. 4 is a schematic representation of one circuit in which the driving of an IGBT switch could damage another component.

FIG. 5 is a schematic representation of circuitry in which the control terminal of an IGBT power switch is driven by a current-source driver that includes a variable current source according to another embodiment of the present disclosure.

FIG. 6 illustrates a discrete component implementation relating to that of FIG. 5.

FIG. 7 shows waveforms from a high-voltage test of the embodiment of FIG. 6.

FIG. 8 is a schematic representation of circuitry in which the control terminal of an IGBT power switch is driven by a current-source driver according to a shared-current embodiment of the present disclosure.

Corresponding reference characters indicate corresponding components throughout the several views of the drawings. Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the teachings herein. Also, common but well-understood elements that are useful or necessary in a commercially feasible embodiment are often not depicted in order to facilitate a less obstructed view of these various embodiments of driving power switches with variable currents.

For didactic purposes, the detailed description is cast in terms of insulated gate bipolar transistor (IGBT) power switches and their terminals (i.e., gates, collectors, and emitters). However, corresponding teachings can be applied to a variety different enhancement-or depletion-mode devices (e.g., bipolar junction transistors (BJTs), metal-oxide-semiconductor field-effect transistors (MOSFETs), or high-electron-mobility transistors (HEMTs)) with electron or hole charge carriers, alone or in combination with other transistors. The devices can be implemented in silicon, silicon carbide, gallium nitride, or other semiconductor materials.

### DETAILED DESCRIPTION

In the following description, numerous specific details are set forth in order to provide a thorough understanding of driving power switches with variable currents. It will be apparent, however, to one having ordinary skill in the art that the specific detail need not be employed to practice the teachings herein. In other instances, well-known materials or methods have not been described in detail in order to avoid obscuring the present disclosure.

Reference throughout this specification to “one embodiment”, “an embodiment”, “one example” or “an example” means that a particular feature, structure, or characteristic described in connection with the embodiment or example is included in at least one embodiment of driving power switches with variable currents. Thus, appearances of the phrases “in one embodiment”, “in an embodiment”, “one example” or “an example” in various places throughout this specification are not necessarily all referring to the same embodiment or example. Furthermore, the particular features, structures or characteristics may be combined in any suitable combinations and/or subcombinations in one or more embodiments or examples. Particular features, structures or characteristics may be included in an integrated circuit, an electronic circuit, a logic circuit, or other suitable components that provide the described functionality. In addition, it is appreciated that the figures provided herewith are for explanation purposes to persons ordinarily skilled in the art and that the drawings, including waveforms and graphs, are not necessarily drawn to scale.

In the context of the present application, when a transistor is in an “off-state” or “off” the transistor blocks current and/or does not substantially conduct current. Conversely, when a transistor is in an “on-state” or “on” the transistor is able to substantially conduct current.

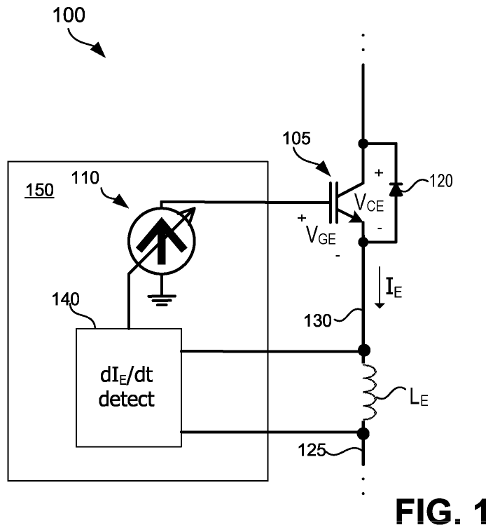

FIG. 1 is a schematic representation of circuitry 100 in which the control terminal of an IGBT power switch 105 is driven by a current-source driver 150 that includes a variable current source 110. The current, with which variable current source 110 drives IGBT power switch 105, is varied in response to a detected rate of change of the emitter current IE. In particular, as discussed further below, the current that drives IGBT power switch 105 is varied to ensure that the rate of change of the emitter current I_{E} is slowed to reduce the “hardness” of switching or commutation of components that are coupled to circuitry 100.

In more detail, diode 120 is coupled between the collector and emitter of IGBT power switch 105. Diode 120 can be integrated with IGBT power switch 105 (i.e., in a “co-pack”) or diode 120 can be a discrete component that is coupled across IGBT power switch 105. In either case, diode 120 imitates the body diode of a MOSFET and provides a freewheeling path for reverse current flow.

The schematically represented implementation of IGBT power switch 105 includes both a main emitter 125 and an auxiliary emitter 130. Main emitter 125 is configured to output emitter current I_{E} from IGBT power switch 105 to a load. In power switching applications, emitter current I_{E} is quite large and even small parasitics can give rise to relatively large differences between the voltage at the main emitter 125 and the voltage at the emitter of the IGBT semiconductor chip. In the schematic representation of FIG. 1, some of these parasitics are represented as a parasitic inductance L_{E}.

In contrast with main emitter 125, auxiliary emitter 130 is not intended to output emitter current I_{E} to a load. Rather, auxiliary emitter 130 is coupled closer to the semiconductor material of the IGBT chip than main emitter 125 and thus presents a relatively lower distortion connection to the emitter region of the IGBT chip. Auxiliary emitter 130 can be used by driver and measurement circuitry to “see” the voltage at the emitter region in the semiconductor material of the IGBT chip without the distortion caused by emitter current I_{E} on main emitter 125.

In general, main emitter 125 and auxiliary emitter 130 will be separate terminals of an IGBT module. IGBT modules (i.e., IGBT power switch modules) generally mount one or more IGBT chips over a baseplate that is molded to connection terminals. The metallization on the IGBT chips—including the base, emitter, and collector of the semiconductor devices—is wired (typically, bond-wired) to the terminals. Dimensions are kept small to reduce internal wiring inductance and other parasitics. In implementations where main emitter 125 and auxiliary emitter 130 are terminals of an IGBT module, parasitic inductance L_{E} includes this internal wiring inductance.

In addition to variable current source 110, current-source driver 150 also includes circuitry 140 that is configured to detect the rate of change of emitter current I_{E}. Circuitry 140 is coupled to main emitter 125 and auxiliary emitter 130. As discussed further below, circuitry 140 is configured to detect the changes in emitter current I_{E} that occur as IGBT power switch 105 switches into and out of conduction. In response to detection of these changes, circuitry 140 varies the current with which variable current source 110 drives IGBT power switch 105. By varying the current that drives IGBT power switch 105, circuitry 140 protects components from large transients that can arise due to “hard” switching of emitter current I_{E}. Although circuitry 140 is illustrated as entirely contained within current-source driver 150, in some implementations, all or a portion of circuitry 140 can be external to current-source driver 150.

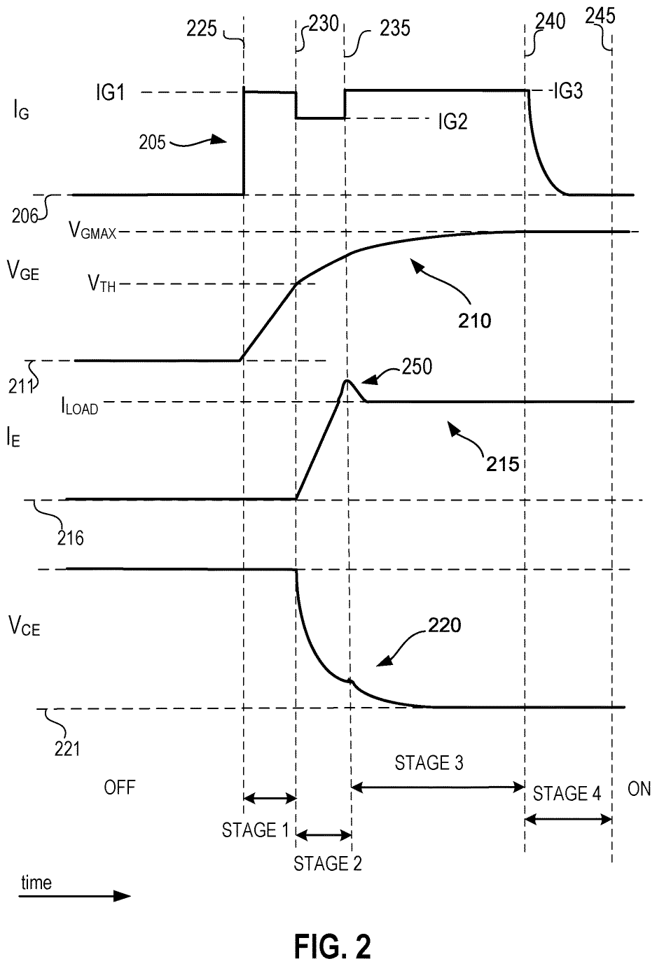

FIG. 2 includes representations of time traces of various waveforms 205, 210, 215, 220 that arise during driving of the gate of an IGBT power switch with a variable current source during a transition from the OFF state to the ON state. As discussed further below, waveforms 205, 210, 215, 220 illustrate switching in which the forward current flow in at least one other diode is interrupted at the same time that this IGBT power switch turns on. For example, when IGBT power switches are assembled in a half-bridge, the anti-parallel or freewheeling diode of another IGBT power switch could be interrupted at the same time that this IGBT power switch turns on.

Regardless of the nature and number of other diodes, the reverse recovery current may flow in the same direction as the current in the IGBT power switch that is turning on. The IGBT power switch that is turning on could transiently conduct both the current that is intended for the load as well as the reverse recovery current of the other diode. Without additional protective measures (e.g., large turn-on gate resistor), the rise time (i.e., the change) of the reverse recovery current could damage the other diode(s). However, by driving the control terminal of the IGBT power switch that is turning on with a variable current source, the IGBT power switch can be turned on relatively quickly while also avoiding damage to the other diode(s) without additional protective measures.

In more detail, waveform 205 is the current with which a variable current source drives the gate of the IGBT power switch during the transition. Vertical position of waveform 205 represents the magnitude of that current with respect to a zero current at dashed line 206.

Waveform 210 is the voltage that arises between the gate and the emitter of the IGBT power switch, i.e., the gate-to-emitter voltage V_{GE}. Vertical position of waveform 210 represents the magnitude of that voltage with respect to an OFF state gate-to-emitter voltage at dashed line 211. OFF state gate-to-emitter voltages in IGBT devices can be zero or negative (for example, −5 to −10 volts is common) and ON state gate-to-emitter voltages are typically below 30 volts (for example, 15-20 volts is common).

Waveform 215 is the emitter current I_{E} that exits the (main) emitter of the IGBT power switch. Vertical position of waveform 215 represents the magnitude of emitter current I_{E} with respect to a zero current at dashed line 216. In the OFF state, the emitter current I_{E} is essentially zero.

Waveform 220 is the voltage across the IGBT power switch, i.e., the collector-to-emitter voltage V_{CE}. Vertical position of waveform 220 represents the magnitude of that voltage with respect to a zero voltage value at dashed line 221. In general, in power switching applications, the collector-to-emitter voltage can range between several hundreds of volts in the OFF state to essentially zero volts in the ON state. For example, in IGBT devices, the collector-to-emitter voltage in the ON state will be a diode-drop plus any voltage drop due the physical limitations of the device.

The vertical scales of waveforms 205, 210, 215, 220 are thus quite different.

For didactic purposes, the transition from the OFF state to the ON state can be divided into four different stages in time. In the schematic representation of waveforms 205, 210, 215, 220, these stages are demarcated by vertical lines 225, 230, 235, 240, 245 that designate different times.

In the OFF state (i.e., before the OFF-to-ON transition), the collector-to-emitter voltage V_{CE} is high (e.g., several hundreds of volts) and the emitter current I_{E} remains essentially zero.

Time 225 represents the start of first stage of the transition from the OFF state to the ON state. At time 225, the variable current source starts to drive the gate of the IGBT power switch with a gate current of magnitude IG1, as represented by waveform 205. The transition from zero gate current before time 225 to the gate current at time 225 is schematically represented in waveform 205 as a vertical line. In real-world devices, the transition will have a finite slope that changes with time.

With the injection of the gate current into the gate beginning, the gate-to-emitter voltage V_{GE} will also begin to rise at time 225, as represented by waveform 210. As represented by waveforms 205, 210, injection of gate current will continue throughout the first stage and the gate-to-emitter voltage V_{GE} will continue to increase. In this first stage, the magnitude of the gate current is schematically represented as constant and the slope of the gate-to-emitter voltage V_{GE} in waveform 210 is schematically represented as a line segment with a constant slope. In real-world devices, deviations will generally occur.

Time 230 represents the end of the first stage and the start of the second stage of the OFF-to-ON transition. Time 230 designates the time when the gate-to-emitter voltage in waveform 210 reaches the threshold voltage V_{TH} of the IGBT device. Threshold voltage V_{TH} is the minimum gate-to-emitter voltage that creates a conductive path between the collector and emitter terminals of the IGBT device such that emitter current I_{E} can flow. In general, the threshold voltage V_{TH} of different IGBT devices will vary somewhat from device to device. As waveform 210 reaches the threshold voltage V_{TH} of the particular IGBT device to which it is coupled, the collector-to-emitter voltage V_{CE} starts to drive the flow of emitter current I_{E} (as represented by waveform 215) and the collector-to-emitter voltage V_{CE} starts dropping (as represented by waveform 220).

The rate of change in the emitter current I_{E} can be detected and used to trigger a decrease in the gate current with which a variable current source drives the gate of the IGBT power switch during the transition. Referring to FIG. 1, the rate of change in the emitter current I_{E} can be detected by circuitry 140. As represented in waveform 205, the variable current source decreases the gate current from a first magnitude IG1 to a second magnitude IG2. The transition between magnitudes IG1 and IG2 is schematically represented as a vertical line and the magnitudes of both IG1 and IG2 are represented as constant. In real-world devices, deviations will generally occur. Further, in some implementations, the magnitude of one or both of IG1 and IG2 can vary over time, e.g., between discrete values or along a continuous path. However, the magnitude of the gate current will be lowered in the second stage.

Also in the second stage, represented in waveform 210, the rate of increase in the gate-to-emitter voltage in waveform 210 decreases. This is due at least in part to the variable current source driving the gate of the IGBT device with the lower magnitude IG2 gate current. Other factors will also influence the rate of increase in the gate-to-emitter voltage, including charging of the input capacitance of the IGBT device.

During the second stage, the magnitude of the emitter current I_{E} reflects both the magnitude of the current that flows to the load and an excess current 250. The total emitter current I_{E} may even rise to a level that is higher than the load current I_{LOAD} with the IGBT device fully conductive. As an aside, for illustrative purposes, the load current I_{LOAD} with the IGBT device in the ON state is shown as having a steady state value, as would be the case with a constant load. This is not necessarily the case and variable loads with variable load currents I_{LOAD} can also be powered.

This excess 250 is a reverse recovery current that flows through one or more other diodes and is transiently conducted by the IGBT device. However, as the other diode(s) recover, the excess current 250 drops. As illustrated by curve 215, the rate of change in the emitter current I_{E} transitions from a relatively high value to a zero and then negative value as the current flowing to the load approaches its steady state value and the reverse recovery current drops.

In general, the same circuitry that detects the high rate of change in the emitter current I_{E} and triggers the decrease in the gate current from magnitude IG1 to IG2 can also detect the zero or negative rate of change in the emitter current I_{E} and triggers an increase in the gate current from magnitude IG2 to magnitude IG3, thus ending the second stage at time 235. For example, the circuitry can detect the high rate of change in the emitter current I_{E} is zero, i.e., that the peak emitter current I_{E} has been reached. Referring to FIG. 1, the rate of change in the emitter current I_{E} can be detected by circuitry 140. In other implementations, the end of the second stage is defined, e.g., by measuring a passage of time.

Regardless of how the second stage is ended, the third stage of the OFF-to-ON transition starts at time 235. The gate current is increased from magnitude IG2 to magnitude IG3 by the variable current source, as shown in waveform 205. As shown in waveform 210, the gate voltage resumes its rise and approaches its maximum value V_{GMAX} as the input capacitance of the IGBT device charges. In some cases, magnitude IG3 can equal magnitude IG1, but this is not necessarily the case. Further, in general and as shown in waveform 210, the gate voltage will approach a maximum value that reflects, e.g., the magnitude of the voltage that supplies the variable current source 110. In many implementations, the magnitude of the gate current will fall below magnitude IG2 and approach zero during the third stage and thereafter.

With the reverse recovery current dropping, the emitter current I_{E} approaches the steady-state load current I_{LOAD} with the IGBT device fully conductive. The rate of decrease in the collector-to-emitter voltage V_{CE} increases, as represented by waveform 220. During the third stage, the collector-to-emitter voltage V_{CE} will eventually fall to a nearly zero voltage value at dashed line 221.

The fourth stage of the OFF-to-ON transition starts at time 240. As shown in waveform 210, the gate voltage has approached its maximum value V_{GMAX} and the gate current falls to nearly zero, as shown in waveform 205. With the gate fully charged, the IGBT device is fully conductive and the emitter current I_{E} remains at the load current I_{LOAD}. Also, the collector-to-emitter voltage V_{CE} remains at a nearly zero voltage value at dashed line 221.

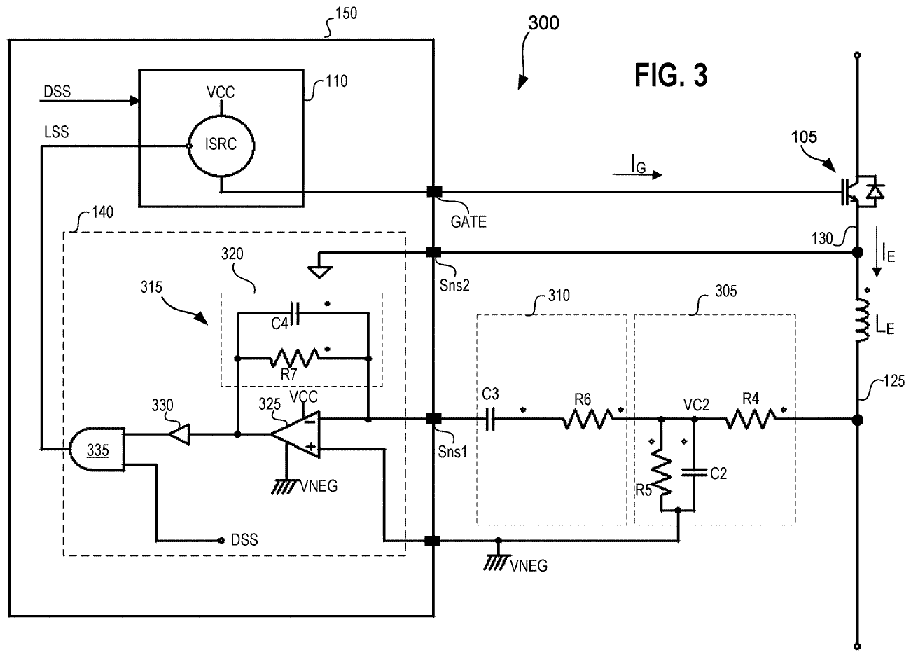

FIG. 3 is a schematic representation of circuitry 300 in which the control terminal of an IGBT power switch 105 is driven by a current-source driver 150 that includes a variable current source 110. Circuitry 300 is one possible implementation of circuitry 100 (FIG. 1) and, like circuitry 100, drives IGBT power switch 105 with a current that is varied to ensure that rate of change of the emitter current I_{E} is slowed to reduce the “hardness” of switching or commutation of components that are coupled to circuitry 300.

In addition to current-source driver 150, circuitry 300 includes interface circuitry 305, 310 that is coupled between a sense input Sns1 of current-source driver 150 and main emitter 125 of IGBT power switch 105. Circuitry 305 is a voltage divider and low-pass filter stage and configured to pass a low-pass filtered version of the voltage on main emitter 125 of IGBT power switch 105 to a sense input of current-source driver 150. In the illustrated implementation, the low-pass filter stage of circuitry 305 is implemented by resistances R4, R5 and a capacitance C2. At low frequencies, the voltage VC2 across resistance R5 and capacitance C2 is a divided version of the voltage on main emitter 125. The particular values of resistances R4, R5 and capacitance C2—and the behavior of the low-pass filter—can be adjusted to the application context.

Interface circuitry 310 is an input stage of a differentiator 315. Differentiator 315 is circuitry that is configured to produce an output that represents the rate of change of the input. A positive change in the input into differentiator 315 with time results in a positive output. A negative or zero change in the input with time causes the output of differentiator 315 to be zero or negative. In addition to the input stage of interface circuitry 310, the illustrated implementation of differentiator 315 also includes a feedback network 320 and an operational amplifier 325. Together, interface circuitry 310 and feedback network 320 define the response of differentiator 315 to changes in the voltage on main emitter 125. In the illustrated implementation, interface circuitry 310 includes a resistance R6 and a capacitance C3; and feedback network 320 includes a resistance R7 and a capacitance C4. Capacitance C3 isolates differentiator 315 from the DC component of the voltage on main emitter 125. In the illustrated implementation, input stage circuitry 310 is external to current-source driver 150 and the particular values of resistance R6 and a capacitance C3—as well as the response of differentiator 315 at different frequencies—can be adjusted to the application context.

In addition to feedback network 320 and amplifier 325, circuitry 140 also includes a second sense input Sns2, a buffer 330, and an AND gate 335. Second sense input Sns2 is coupled to the auxiliary emitter 130 of IGBT power switch 105. In the illustrated implementation, second sense input Sns2 is coupled to a reference node. The voltage at second sense input Sns2 may serve as a reference for some or all of the circuitry in current-source driver 150. For example, in the illustrated implementation, negative voltage VNEG can be defined with respect to the reference voltage at second sense input Sns2. In some implementations, current-source driver 150 includes a voltage source (e.g., a battery or a power converter, not shown) that defines negative voltage VNEG with respect to the reference voltage at second sense input Sns2.

In the illustrated implementation, negative voltage VNEG is coupled to the non-inverting input of amplifier 325 and provides a reference against which the rate of change of the voltage on the inverting input of amplifier 325 is compared. Since negative voltage VNEG itself is referenced to the voltage on the auxiliary emitter 130 and the voltage on the inverting input of amplifier 325 represents the changing component of voltage on the main emitter 125, differentiator 315 differentiates the voltage that arises across parasitic inductance L_{E}. Even though parasitic inductance L_{E} is quite small in value, changes in the emitter current I_{E} with time can be isolated—even in the context of a high power switching environment. In particular, voltage swings that are due to factors other than the changes in the emitter current I_{E} will generally impact the voltage on the auxiliary emitter 130 and the voltage on the main emitter 125 to nearly the same extent. However, the voltage that arises across parasitic inductance L_{E} is impacted most by changes in the emitter current I_{E}.

Further, by using parasitic inductance L_{E} as a sense inductor, power losses due to other sense components are avoided.

Buffer 330 is coupled to the output of differentiator 315 and configured to decouple that output from AND gate 335. The inputs of AND gate 335 are coupled to receive the buffered output of differentiator 315 and a drive state signal DSS. Drive state signal DSS can be, e.g., a pulse-width modulation (PWM) control signal or other signal that indicates when IGBT power switch 105 is to be in the ON state. In the illustrated implementation, a high drive state signal DSS indicates that IGBT power switch 105 is to be in the ON state. In the event that both the IGBT power switch 105 is to be in the ON state and the voltage difference between main emitter 125 of IGBT power switch and the auxiliary emitter 130 increases (i.e., the di/dt of load current 115 is positive), then differentiator 315 and AND gate 335 will output a high state signal that is received by variable current source 110.

Both drive state signal DSS and the logic state signal LSS, that is output from AND gate 335, are coupled to variable current source 110. Variable current source 110 is configured to respond to drive state signal DSS being in a state that indicates that IGBT power switch 105 is to be in the ON state by driving the gate of the IGBT power switch 105 with a gate current that has first magnitude IG1 (FIG. 2). Variable current source 110 is configured to respond to the drive state signal DSS being in a state that indicates that IGBT power switch 105 is to be in the ON state and the logic state signal LSS from AND gate 335 indicating that the di/dt of the load current 115 is positive by driving the gate of the IGBT power switch 105 with a gate current that has second magnitude IG2 (FIG. 2).

In the implementation illustrated in FIG. 2, variable current source 110 will continue to drive the gate of the IGBT power switch 105 with a gate current that has constant second magnitude IG2 throughout the second stage. As mentioned above, this is not necessarily the case. However, at some point, the rate of change in the emitter current I_{E} will transition from a relatively high value (i.e., positive) to a zero and then negative value as the current flowing to the load approaches its steady state value and the reverse recovery current drops. Differentiator 315 will respond by outputting a low state signal that changes the logic state and logic state signal LSS of AND gate 335. The changed logic state is received by variable current source 110, which responds by driving the gate of the IGBT power switch 105 with a gate current that has a higher magnitude, e.g., IG3.

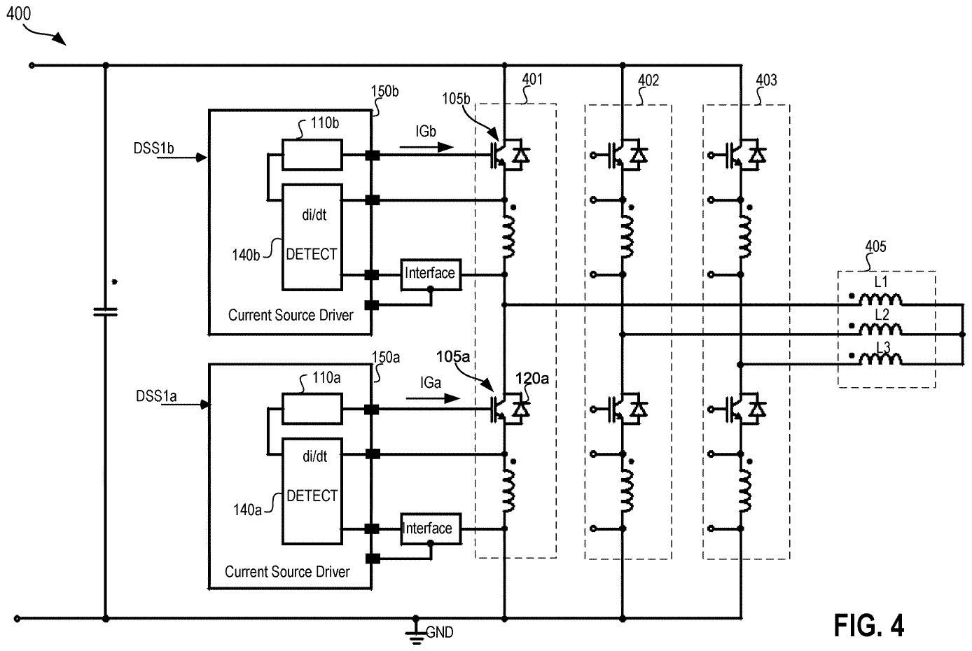

FIG. 4 is a schematic representation of one circuit in which the driving of IGBT power switch 105 could damage another component, namely, a variable-frequency drive in which an inverter 400 is coupled to provide power to a three-phase motor 405. Inverter 400 includes half-bridge circuits 401, 402, 403 and a collection of current-source drivers 150a, 150b, . . . For the sake of illustration, only current-source drivers 150a, 150b that drive the IGBTs in half-bridge circuit 401 are shown. Additionally, with reference to FIG. 3, the elements in FIG. 4 may be indicated with like alphanumeric labels distinguishing low-side elements or signals with an additional “a” and high-side elements or signals with an additional “b”.

As illustrated, three-phase motor 405 includes a set of motor winding inductances L1-L3.

Each half-bridge circuit 401, 402, 403 couples and decouples a respective motor winding inductance L1-L3 to a high or low rail in phase to drive three-phase motor 405. In an illustrative example, during a first phase, the high side IGBT power switch 105b in half-bridge circuit 401 and a low side IGBT power switch 105a in half-bridge circuit 402 will be conductive and current will flow from the high rail to the low rail through winding inductances L1, L2. To transition to a second phase, these high side and low side IGBT power switches will be turned off and another high side and low side IGBT power switch will be turned on.

With these high side and low side IGBT power switches being turned off, the winding inductances L1, L2 will resist demagnetization and the end of current flow by forcing the current through the low-side diode of 401 and the high-side diode of 402. Once the high side and low side IGBT power switches are turned-on again, a reverse recovery current may flow through diode 120a in half-bridge circuit 401. Further, this reverse recovery current will flow through high side IGBT power switch 105b in half-bridge circuit 401, adding to the emitter current I_{E} in high side IGBT power switch 105b. Such an addition of currents is illustrated in waveform 215 (FIG. 2) and can be sensed by comparing the voltages of the main emitter and auxiliary emitter of high side IGBT power switch 105b, as discussed above.

A number of implementations have been described. Nevertheless, it will be understood that various modifications may be made. For example, multiple gate current magnitudes may be used. As another example, variable current sources and main emitter and auxiliary emitter voltage sensing may be used to control the transitions of IGBT power switches from an ON state to an OFF state.

As yet another example, a voltage source gate driver can be used to achieve variable gate drive currents. In particular, instead of switching between currents, different gate turn-on resistances can be used in conjunction with a voltage source gate driver to achieve variable driving currents. For example, in the first stage, the gate turn-on resistance could have a value R, leading to a relatively high gate current and fast switching. In the second stage, the gate turn-on resistance could have a value 4R, leading to a relatively lower gate current and slower switching. In the third stage, the gate turn-on resistance could have a value R or lower (e.g., zero gate turn-on resistance). As with a current source gate driver, the rate of change in the current flowing through the power switch can be used to trigger the transitions between stages.

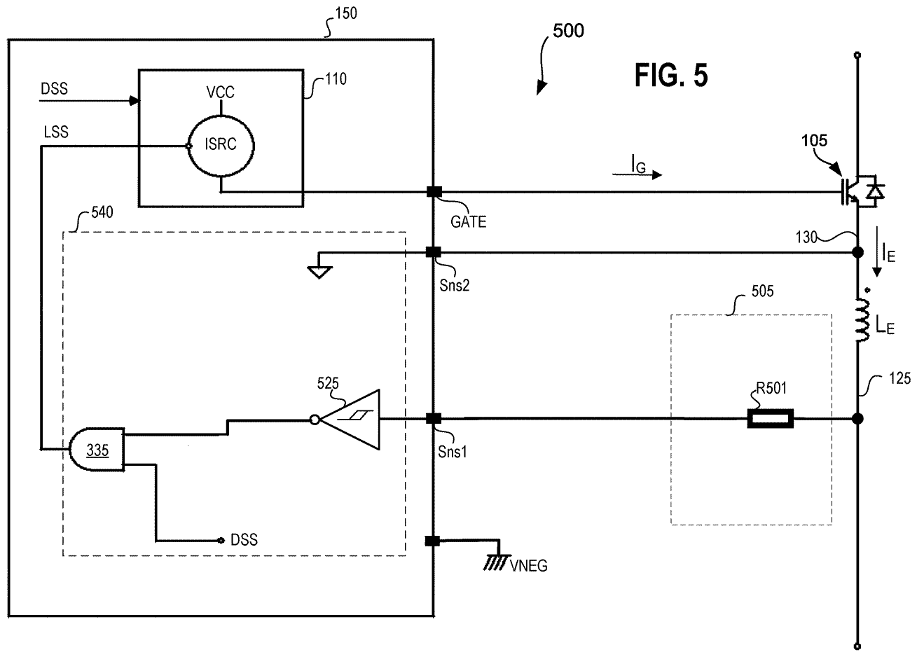

Alternatively, and additionally, FIG. 5 is a schematic representation of circuitry 500 according to another embodiment of the present disclosure. Circuitry 500 is like circuitry 300, except circuitry 540 replaces circuitry 140, and interface circuitry 505 replaces interface circuitry 305, 310.

As illustrated in FIG. 5, interface circuitry 505 includes resistance R501; and circuitry 540 includes a Schmitt trigger 525. As one of skill in the art may appreciate, a Schmitt trigger is a type of comparator with hysteresis. Schmitt trigger 525 with resistance R501 may be used instead of circuitry 305, 310, buffer 330, and differentiator 315. Resistor R501 is electrically coupled between main emitter 125 and an input of Schmitt trigger 525; and the output of Schmitt Trigger 525 may be coupled to an input of AND gate 335.

As an alternative to circuitry 140 and interface circuitry 305, 310, circuitry 540 with interface circuitry 505 may advantageously reduce component count for simplified integration and avail faster response time. For instance, using a simple Schmitt trigger 525, instead of an operational amplifier 325, may advantageously reduce current consumption since the simple Schmitt trigger does not consume as much current as an operational amplifier 325 tailored for high gain and high bandwidth. Additionally, having fewer components may simplify an application specific integrated circuit (ASIC) implementation of circuitry 540 with interface circuitry 505. Moreover, because interface circuitry 505 does not require a low pass filter like that of interface circuitry 305, the overall response time of a system including circuitry 540 may be faster. This in turn may reduce delay-induced switching losses of a power module.

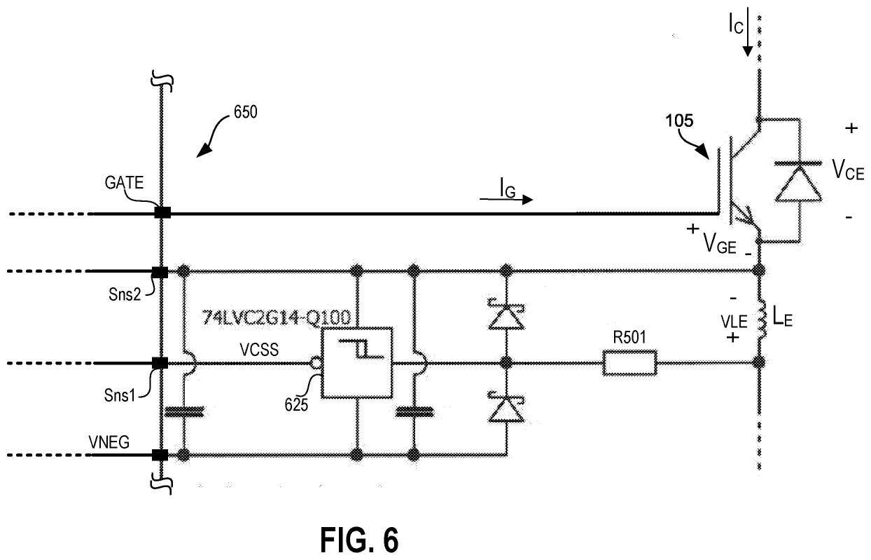

FIG. 6 illustrates a discrete component implementation relating to that of FIG. 5. Current source driver 650 may be like current source driver 150 of FIG. 5, except it does not include Schmitt trigger 525. Instead, Schmitt trigger 625 is realized with a discrete component (e.g., component part number 74LVC2G14-q100) external to the current source driver 650; and the output signal VCSS from Schmitt trigger 625 may be provided to the sense input Sns1 of current source driver 650.

Also, in the discrete component implementation of FIG. 6, the resistance R501 may equal one hundred ohms (100 ohms).

Also illustrated are the voltage VLE across inductance L_{E} and the gate-to-emitter voltage V_{GE}, collector-to-emitter voltage V_{CE}, gate drive current I_{G}, and collector current I_{C} of IGBT power switch 105.

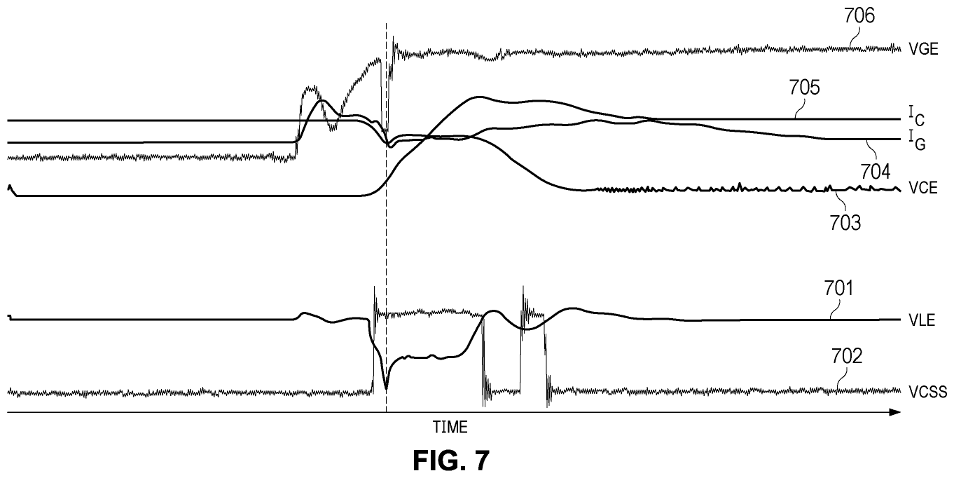

FIG. 7 shows waveforms 701-706 from a high-voltage test of the implementation of FIG. 6. With reference to FIG. 6, waveforms 701-706 may correspond with voltage VLE, signal VCSS, voltage V_{CE}, current I_{G}, current I_{C}, and voltage V_{GE}. During operation of the discrete component implementation of FIG. 6, Schmitt trigger 525 may provide output signal VCSS for detecting the start and end of diode commutation.

Additionally, as depicted by waveform 701 of voltage VLE and waveform 702 of voltage signal VCSS, the Schmitt trigger 525 may change state (i.e., transition from a logic high to a logic low or from a logic low to a logic high) in response to the time derivative of waveform 701.

Although the embodiments of FIG. 5 and FIG. 6 illustrate an implementation using a single Schmitt trigger 525 or Schmitt trigger 625, respectfully, other configurations are possible.

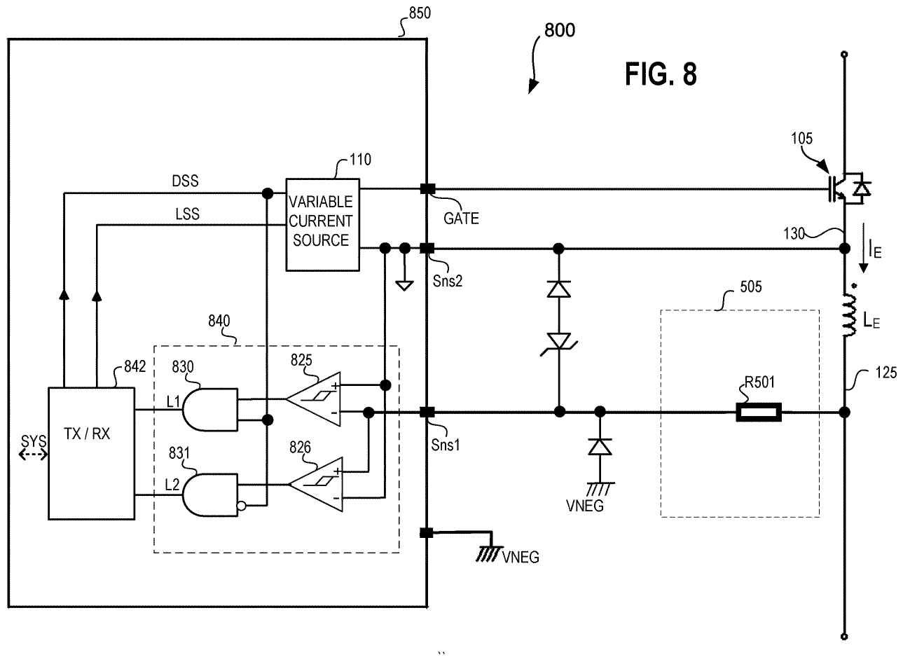

For instance, FIG. 8 illustrates circuitry 800 according to a shared-current embodiment of the present disclosure. In comparison to circuitry 500, circuitry 800 includes current source driver 850 instead of current source driver 150 and a transceiver 842. Like current source driver 150, current source driver 850 may be tailored for driving IGBT power switch 105 with variable current source 110; however, unlike current source driver 150, current source driver 850 may also drive IGBT power switch 105 so that it shares current with one or more additional IGBT power switches operating in parallel.

The concept of operating IGBT power switches in parallel is discussed in U.S. Patent Application No. 2025/0112633(US2025/0112633A1), the entirety of which is incorporated by reference herein. In the approach of US2025/0112633A1, collector-to-emitter voltage (VCE) measurement circuitry may provide information to a system transceiver, which in turn may communicate system-wide information useful for paralleling more than one power switch. However, sensing collector-to-emitter voltage (VCE) with VCE measurement circuitry may be difficult to implement in practice.

Therefore, as an alternative to VCE measurement circuitry, current source driver 850 uses circuitry 840 to detect the rate of change of emitter current I_{E}. Circuitry 840 includes comparators 825, 826 and AND gates 830, 831. Like Schmitt trigger 525, comparators 825, 826 may sense the rate of change of emitter current I_{E}. Comparator 825 with AND gate 830 may provide a logic state signal L1 in response to the change of emitter current I_{E} during the turn-on of IGBT power switch 105 while comparator 826 with AND gate 831 may provide a logic state signal L2 in response the rate of change of emitter current I_{E} during the turn-off of IGBT power switch 105.

The transceiver 842 receives the logic state signals L1, L2 and communicates system information SYS for processing. For instance, the system information may use logic state signals L1, L2 to determine the amount of delay IGBT power switch 105 has relative to an additional IGBT power switch within the system. Based on the system information SYS, transceiver 842 may provide logic state signal LSS and drive state signal DSS to variable current source 110 so that IGBT power switch 105 shares current and operates in parallel with the additional IGBT power switch.

### CONCLUSION

The above description of illustrated examples of the present disclosure, including what is described in the Abstract, is not intended to be exhaustive or to be limitation to the precise forms disclosed. While specific embodiments of, and examples for driving power switches with variable currents are described herein for illustrative purposes, various equivalent modifications are possible without departing from the broader spirit and scope of the present disclosure. Indeed, it is appreciated that the specific example voltages, currents, frequencies, power range values, times, etc., are provided for explanation purposes and that other values may also be employed in other embodiments and examples in accordance with the teachings herein.

The foregoing description may refer to elements or features as being “connected” or “coupled” together. As used herein, unless expressly stated otherwise, “connected” or “electrically connected” means that one element/feature is directly or indirectly connected to another element/feature, and not necessarily mechanically. Likewise, unless expressly stated otherwise, “coupled” or “electrically coupled” means that one element/feature is directly or indirectly coupled to another element/feature, and not necessarily mechanically. Thus, although the various schematics shown in the figures depict example arrangements of elements and components, additional intervening elements, devices, features, or components may be present in an actual embodiment (assuming that the functionality of the depicted circuits is not adversely affected). Additionally, components may be excluded for the sake of providing an unencumbered illustration of the teachings herein.

Moreover, conditional language used herein, such as, among others, “can,” “could,” “might,” “may,” “e.g.,” “for example,” “such as” and the like, unless specifically stated otherwise or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding whether these features, elements and/or states are included or are to be performed in any particular embodiment.

While certain embodiments have been described, these embodiments have been presented by way of example only and are not intended to limit the scope of the disclosure. Indeed, the novel apparatus, methods, and systems described herein may be embodied in a variety of other forms; furthermore, various omissions, substitutions, and changes in the form of the methods and systems described herein may be made without departing from the spirit of the disclosure. For example, while the disclosed embodiments are presented in a given arrangement, alternative embodiments may perform similar functionalities with different components and/or circuit topologies, and some elements may be deleted, moved, added, subdivided, combined, and/or modified. Each of these elements may be implemented in a variety of different ways. Any suitable combination of the elements and acts of the various embodiments described above can be combined to provide further embodiments. Accordingly, the scope of the present invention is defined only by reference to the appended claims.

Although the claims presented here are in single dependency format for filing at the USPTO, it is to be understood that any claim may depend on any preceding claim of the same type except when that is clearly not technically feasible.

What is claimed is:

1. A gate driver for a control terminal of a power switch, the gate driver comprising:
di/dt sense circuitry that is configured to sense a rate of change of a current flowing through the power switch and generate a signal indicative of a sensed rate of change of the current flowing through the power switch; and
driver circuitry configured to output a variable drive current to a control terminal of the power switch, wherein the gate driver is configured to decrease, during a transition from an OFF state to an ON state, a magnitude of a drive current in response to the signal indicating that the sensed rate of change in the current flowing through the power switch is positive.

2. The gate driver of claim 1, wherein the driver circuitry comprises:
a first input coupled to a first sense terminal of the driver circuitry; and
a second input coupled to a second sense terminal of the driver circuitry,
wherein the di/dt sense circuitry is configured to detect a difference in a rate of change of respective voltages at the first and second sense terminals.

3. The gate driver of claim 2, wherein the di/dt sense circuitry includes a differentiator configured to provide a signal indicative of the difference.

4. The gate driver of claim 2, wherein the di/dt sense circuitry includes a comparator configured to change state in response to a difference of a voltage at the first input with reference to a voltage at the second input.

5. The gate driver of claim 1, wherein the driver circuitry is configured to increase magnitude of the drive current in response to the signal indicating that the rate of change in the current flowing through the power switch is zero or negative.

6. The gate driver of claim 1, wherein the driver circuitry includes a variable current source.

7. The gate driver of claim 1, wherein the driver circuitry includes a voltage source and a variable gate turn-on resistance.

8. The gate driver of claim 1, wherein a power converter comprises:
the gate driver; and
a power switch module, the power switch module comprising an inductance that impedes main current flow through the power switch module, wherein the gate driver is coupled to sense a voltage difference across the inductance.

9. The power converter of claim 8, wherein the inductance is a parasitic inductance.

10. The power converter of claim 9, wherein the power switch module comprises:
a main output terminal configured to output current to a load, and
an auxiliary output terminal coupled closer to semiconductor material of the power switch,
wherein the parasitic inductance is coupled between the main output terminal and the auxiliary output terminal.

11. The power converter of claim 8, wherein the power switch module comprises an IGBT power switch.

12. A power converter comprising:
a first IGBT power switch module comprising:
a gate;
a main emitter configured to output emitter current to a load;
an auxiliary emitter; and
an inductance between the main emitter and the auxiliary emitter; and
a current-source gate driver comprising:
a variable current source configured to provide current to the gate of the first IGBT power switch module;
a first sense input coupled to the main emitter;
a second sense input coupled to the auxiliary emitter; and
circuitry configured to determine a derivative of a voltage on the main emitter and output a signal indicative of the derivative.

13. The power converter of claim 12, wherein the inductance is a parasitic inductance.

14. The power converter of claim 12, wherein an inverter comprises the power converter.

15. The power converter of claim 12, wherein the variable current source is configured to receive the signal indicative of the derivative and, in response, to vary an output current during a transition from an OFF state to an ON state.

16. The power converter of claim 15, wherein the variable current source is configured to decrease the output current in response to the signal indicating that a di/dt of an emitter (load) current has a positive gradient 17. The power converter of claim 16, wherein the variable current source is configured to increase the output current in response to the signal indicating that the di/dt of the emitter (load) current has a zero or negative gradient.

18. The power converter of claim 12, further comprising:
a second IGBT power switch module, wherein the second IGBT power switch module and the first IGBT power switch module share an output current based, at least in part, on the signal indicative of the derivative.
